(19) United States
(12) Patent Application Publication
(10) Pub. No.: US 2023/0196430 A1
(43) Pub. Date: Jun. 22, 2023

(54) Compression of Lookup Data Communicated by Nodes in an Electronic Device

(71) Applicant: Advanced Micro Devices, Inc., Santa Clara, CA (US)

(72) Inventors: Sarunya Pumma, Austin, TX (US); Abhinav Vishnu, Austin, TX (US)

(21) Appl. No.: 17/559,636

(22) Filed: Dec. 22, 2021

(51) Int. Cl. G06Q 30/06

(52) U.S. Cl. CPC G06Q 30/0625

(57) ABSTRACT

An electronic device includes multiple nodes. Each node generates compressed lookup data to be used for processing instances of input data through a model using input index vectors from a compressed set of input index vectors for each part among multiple parts of a respective set of input index vectors. Each node then communicates compressed lookup data for a respective part to each other node.

### BACKGROUND

### Related Art

Some electronic devices perform operations for processing instances of input data through computational models, or “models,” to generate outputs. There are a number of different types of models, for each of which electronic devices generate specified outputs based on processing respective instances of input data. For example, one type of model is a recommendation model. Processing instances of input data through a recommendation model causes an electronic device to generate outputs such as ranked lists of items from among a set of items to be presented to users as recommendations (e.g., products for sale, movies or videos, social media posts, etc.), probabilities that a particular user will click on/select a given item if presented with the item (e.g., on a web page, etc.), and/or other outputs. For a recommendation model, instances of input data therefore include information about users and/or others, information about the items, information about context, etc. FIG. 1 presents a block diagram illustrating a recommendation model 100 with sub-models 102-104. Sub-model 102 is a multilayer perceptron 106 used for processing dense features 108 in input data. Sub-model 104 is a generalized linear model used for processing categorical features 110 in input data via table lookups in embedding tables 112. The outputs of each of sub-models 102 and 104 are combined in combination 114 to form a combined intermediate value (e.g., by combining vector outputs from each of sub-model 102 and 104). From combination 114, the combined intermediate value is sent to multilayer perceptron 116 to be used for generating a model output 118. One example of a model arranged similarly to model 100 is the deep learning recommendation model (DLRM) described by Naumov et al. in the paper “Deep Learning Recommendation Model for Personalization and Recommendation Systems,” arXiv:1906.00091, May 2019. In some cases, models are used in production scenarios at very large scales. For example, recommendation models such as model 100 may be used for recommending videos from among millions of videos to each user among millions of users (e.g., on a website such as YouTube) or for choosing items for sale to be presented each user from among millions of users (e.g., on a website such as Amazon).

In some electronic devices, multiple compute nodes, or “nodes,” are used for processing instances of input data through models to generate outputs. These electronic devices can include many nodes, with each node including one or more processors and a local memory. For example, the nodes can be or include interconnected graphics processing unit (GPUs) on a circuit board or in an integrated circuit chip, server nodes in a data center, etc. When using multiple nodes for processing instances of input data through models, different schemes can be used for determining where model data is to be stored in memories in the nodes. Generally, model data includes information that describes, enumerates, and/or identifies arrangements or properties of internal elements of a model—and thus defines or characterizes the model. For example, for model 100, model data includes embedding tables 112, information about the internal arrangement of multilayer perceptrons 106 and 116, and/or other model data. One scheme for determining where model data is stored in memories in the nodes is “data parallelism.” For data parallelism, full copies of model data are replicated/stored in the memory in individual nodes. For example, a full copy of model data for multilayer perceptrons 106 and/or 116 can be replicated in each node that performs processing operations for multilayer perceptrons 106 and/or 116. Another scheme for determining where model data is stored in memories in the nodes is “model parallelism.” For model parallelism, separate portions of model data are stored in the memory in individual nodes. The memory in each node therefore stores a different part—and possibly a relatively small part—of the particular model data. For example, for model 100, a different subset of embedding tables (i.e., the model data) from among embedding tables 112 can be stored in the local memory of each node among multiple nodes. For instance, given M embedding tables and N nodes, the memory in each node can store a subset that includes M/N of the embedding tables (M=100, 1000, or another number and N=10, 50, or another number). In some cases, model parallelism is used where particular model data is sufficiently large in terms of bytes that it is impractical or impossible to store a full copy of the model data in any particular node's memory. For example, embedding tables 112 can include thousands of embedding tables that are too large as a group to be stored in any individual node's memory and thus the embedding tables are distributed to the local memories in multiple nodes.

In electronic devices in which portions of model data are distributed among multiple nodes in accordance with model parallelism, individual nodes may need model data stored in memories in other nodes for processing instances of input data through the model. For example, when the individual embedding tables from among embedding tables 112 in model 100 are stored in the local memories of multiple nodes, a given node may need lookup data from the individual embedding tables stored in other node's local memories for processing instances of input data. In this case, each node receives or acquires indices (or other records) that identify lookup data from the individual embedding tables stored in that node's memory that is needed by each other node. Each node then acquires/looks-up and communicates, to each other node, respective lookup data from the individual embedding tables stored in that node's memory (or data generated based thereon, e.g., by combining or adding multiple rows, etc.), FIG. 2 presents a block diagram illustrating an all-to-all communication of lookup data (i.e., information from rows of embedding tables) between nodes when processing instances of input data through a model. For the example in FIG. 2, there are four nodes communicatively coupled via a communication (COMM) fabric (e.g., an interconnect, a system bus, network, etc.) and the model is assumed to be model 100, with each of the four nodes having individual embedding tables from embedding table 112 stored in that node's local memory. In addition, it is assumed that processing instances of input data through the model in each node requires lookup data from embedding table stored in other node's memories (i.e., requires lookups for corresponding indices in embedding tables stored in the other node's memories). As can be seen in FIG. 2, therefore, each node performs lookups in the individual embedding tables in that node's memory to acquire lookup data from the individual embedding tables for the other nodes—and for that node itself. For example, as shown in the top half of FIG. 2, node0 acquires lookup data labeled as 00, 01, 02, and 03 from the embedding tables stored in the local memory in node0. The nodes then perform an all-to-all communication via the communication fabric to communicate lookup data acquired from the embedding tables to the other nodes. For the all-to-all communication, each node communicates lookup data needed by each other node to that other node in a “scatter” communication as shown by the arrows overlapping/through the communication fabric in FIG. 2. For example, node0 communicates lookup data 01 to node1, lookup data 02 to node2, and lookup data 03 to node3 (node0 itself uses lookup data 00). Each node therefore receives the lookup data that the node needs from the individual embedding tables stored in other node's memories. This is shown in the bottom half of FIG. 2 as each node including that node's lookup data, such as node0 including lookup data 00 from node0, 01 received from node1, 02 received from node2, and 03 received from node3, etc.

In many electronic devices, a significant part of the computational and/or communication effort expended by nodes for processing instances of input data through a model is expended on the above described acquisition of lookup data (i.e., model data) for other nodes and/or all-to-all communication of lookup data to the other nodes. Performing the lookups and the all-to-all communication can therefore absorb a considerable amount of processing capacity for the nodes and add latency to operations for processing instances of input data through the model.

### BRIEF DESCRIPTION OF THE FIGURES

FIG. 1 presents a block diagram illustrating a recommendation model.

FIG. 2 presents a block diagram illustrating an all-to-all communication of lookup data between nodes.

FIG. 3 presents a block diagram illustrating a full set of input index vectors and respective sets of input index vectors in accordance with some embodiments.

FIG. 4 presents a block diagram illustrating an electronic device in accordance with some embodiments.

FIG. 5 presents a block diagram illustrating the generation of compressed sets of input index vectors and records of duplicate input indices in accordance with some embodiments.

FIG. 6 presents a block diagram illustrating operations for generating compressed lookup data in accordance with some embodiments.

FIG. 7 presents a block diagram illustrating operations for decompressing compressed lookup data in accordance with some embodiments.

FIG. 8 presents a flowchart illustrating operations for processing instances of input data through a model using compressed lookup data in accordance with some embodiments.

FIG. 9 presents a flowchart illustrating a process for generating compressed lookup data in accordance with some embodiments.

FIG. 10 presents a flowchart illustrating a process for decompressing compressed lookup data in accordance with some embodiments.

Throughout the figures and the description, like reference numerals refer to the same figure elements.

### DETAILED DESCRIPTION

The following description is presented to enable any person skilled in the art to make and use the described embodiments and is provided in the context of a particular application and its requirements. Various modifications to the described embodiments will be readily apparent to those skilled in the art, and the general principles described herein may be applied to other embodiments and applications. Thus, the described embodiments are not limited to the embodiments shown, but are to be accorded the widest scope consistent with the principles and features described herein.

### Terminology

In the following description, various terms are used for describing embodiments. The following is a simplified and general description of some of the terms. Note that these terms may have significant additional aspects that are not recited herein for clarity and brevity and thus the description is not intended to limit these terms.

Functional block: functional block refers to a set of interrelated circuitry such as integrated circuit circuitry, discrete circuitry, etc. The circuitry is “interrelated” in that circuit elements in the circuitry share at least one property. For example, the circuitry may be included in, fabricated on, or otherwise coupled to a particular integrated circuit chip, substrate, circuit board, or portion thereof, may be involved in the performance of specified operations (e.g., computational operations, control operations, memory operations, etc.), may be controlled by a common control element and/or a common clock, etc. The circuitry in a functional block can have any number of circuit elements, from a single circuit element (e.g., a single integrated circuit logic gate or discrete circuit element) to millions or billions of circuit elements (e.g., an integrated circuit memory). In some embodiments, functional blocks perform operations “in hardware,” using circuitry that performs the operations without executing program code.

Data: data is a generic term that indicates information that can be stored in memories and/or used in computational, control, and/or other operations. Data includes information such as actual data (e.g., results of computational or control operations, outputs of processing circuitry, inputs for computational or control operations, variable values, sensor values, etc.), files, program code instructions, control values, variables, and/or other information.

### Models

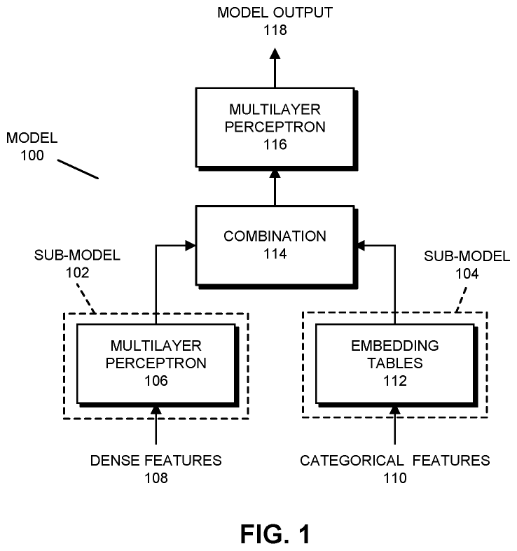

In the described embodiments, computational nodes, or “nodes,” in an electronic device perform operations for processing instances of input data through a computational model, or “model.” A model generally includes, or is defined as, a number of operations to be performed on, for, or using instances of input data to generate corresponding outputs. For example, in some embodiments, the nodes perform operations for processing instances of input data through such as model 100 as shown in FIG. 1. Model 100 is one embodiment of a recommendation model that is used for generating ranked lists of items for presentation to a user, for generating estimates of likelihoods of users clicking on/selecting items presented on a website, etc. For example, model 100 can generate ranked lists of items such as videos on a video presentation website, software applications to purchase from among a set of software applications provided on an Internet application store, etc. Model 100 is sometimes called a “deep and wide” model that uses the combined output of sub-model 102 (the “deep” part of the model) and sub-model 104 (the “wide” part) for generating the ranked list of items. As described above, in some embodiments, model 100 is similar to the deep learning recommendation model (DLRM) described by Naumov et al. in the paper “Deep Learning Recommendation Model for Personalization and Recommendation Systems.”

Models are defined or characterized by model data, which is or includes information that describes, enumerates, and identifies arrangements or properties of internal elements of a model. For example, for model 100, the model data includes embedding tables 112 such as tables, hashes, or other data structures including index-value pairings; configuration information for multilayer perceptrons 106 and 116 such as weights, bias values, etc. used for processing operations for hidden layers within the multilayer perceptrons (not shown in FIG. 1); and/or other model data. In the described embodiments, certain model data is handled using model parallelism (other model data may be handled using data parallelism). Portions of at least some of the model data are therefore distributed among multiple nodes in the electronic device, with separate portions of the model data being stored in local memories in each of the nodes. For example, assuming that model 100 is the model, individual embedding tables from among embedding tables 112 can be stored in local memories in some or all of the nodes. For instance, given M embedding tables in embedding tables 112 and N nodes, the local memory in each node can store MN embedding tables (M=200, 1200, or another number and N=20, 50, or another number).

For processing instances of input data through a model, the instances of input data are processed through internal elements of the model to generate an output from the model. Generally, an “instance of input data” is one piece of the particular input data that is to be processed by the model, such as information about a user to whom a recommendation is to be provided for a recommendation model, information about an item to be recommended, etc. Using model 100 as an example, each instance of input data includes dense features 108 and categorical features 110, which include and/or are generated based on information about a user, context information, item information, and/or other information.

In some embodiments, for processing instances of input data through the model, a number of instances of input data are divided up and assigned to each of multiple nodes in an electronic device to be processed therein. As an example, assume that there are eight nodes and 32,000 instances of input data to be processed. In this case, evenly dividing the instances of input data up among the eight nodes means that each node will process 4000 instances of input data through the model. Further assume that model 100 is the model and that there are 1024 total embedding tables 112, with 128 different embedding tables stored in the local memory in each of the eight nodes. For processing instances of input data through the model, each of the eight nodes receives the dense features 108 for all the instances of input data to be processed by that node—and therefore receives the dense features for 4,000 instances of input data. Each node also receives a respective portion of the categorical features 110 for all 32,000 instances of input data. The respective portion for each node includes a portion of the categorical features for which the node is to perform lookups in locally stored embedding tables 112. Generally, the categorical features 110 include 1024 input index vectors, with one input index vector for each embedding table. Each input index vector includes elements with indices to be looked up in the corresponding embedding table for each instance of input data and thus each of the 1024 input index vectors has 32,000 elements. For receiving the respective portion of the categorical features 110, each node receives an input index vector for each of the 128 locally stored embedding tables with 32000 indices to be looked up in that locally stored embedding table. In other words, in the respective set of input index vectors, each node receives a different 128 of the 1024 input index vectors.

After receiving dense features 108 and categorical features 110, each node uses the respective embedding tables for processing the categorical features 110. For this operation, each node performs lookups in the embedding tables stored in that node's memory using indices from the received input index vectors to acquire lookup data needed for processing instances of input data. Continuing the example, based on the 32,000 input indices in each of the 128 input index vectors, each node performs 32,000 lookups in each of the 128 locally stored embedding tables to acquire both that node's own data and data that is needed by the other seven nodes for processing their respective instances of input data. Each node then communicates lookup data acquired during the lookups to other nodes in an all-to-all communication via a communication fabric. For this operation, each node communicates a portion of the lookup data acquired from the locally stored embedding table to the other node that is to use the lookup data for processing instances of input data. Continuing the example from above, each node communicates the lookup data from the 128 locally stored embedding tables for processing the respective 4,000 instances of input data to each other node, so that each other node receives a block of lookup data that is 128×4,000 in size. For example, a first node can communicate a block of lookup data for the second 4,000 instances of input data to a second node, a block of lookup data for the third 4,000 instances of input data to a third node, and so forth (the first node keeps the lookup data for the first 4,000 instances of input data for processing its own instances of input data).

Each of the nodes additionally processes dense features 108 through multilayer perceptron 106 to generate an output for multilayer perceptron 106. Each node next combines the outputs from multilayer perceptron 106 and that node's lookup data in combination 114 to generate corresponding intermediate values (e.g., combined vectors, etc.). For this operation, that node's lookup data includes the lookup data acquired by that node from the locally stored embedding tables as well as all the portions of lookup data received by that node from the other nodes. As an output of this operation each node produces 4,000 intermediate values, one intermediate value for each instance of input data being processed in that node. Each node processes each of that node's intermediate values through multilayer perceptron 116 to generate model output 118. The model output 118 for each instance of input data in each node is in the form of a ranked list (e.g., a vector or other listing) of items to be presented to a user as a recommendation, an identification of a probability of a user clicking on/selecting an item presented on a website, etc.

Although a particular model (i.e., model 100) is used as an example herein, the described embodiments are operable with other types of models. Generally, in the described embodiments, any type of model can be used for which separate embedding tables are stored in local memories in multiple nodes in an electronic device (i.e., for which the embedding tables are distributed using model parallelism). In addition, although eight nodes are used for describing processing 32,000 instances of input data through a model in the example above, in some embodiments, different numbers of nodes are used for processing different numbers of instances of input data. Generally, in the described embodiments, any number and/or arrangement of nodes in an electronic device can be used for processing instances of input data through a model, as long as some or all of the nodes have a local memory in which separate embedding tables are stored.

### Input Index Vectors

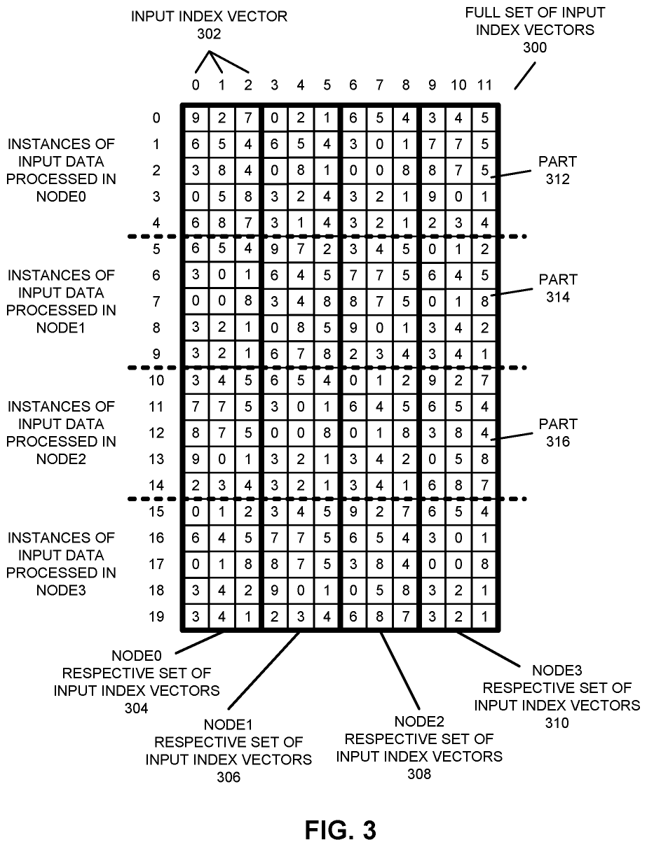

In the described embodiments, nodes perform lookups in embedding tables stored in local memories in the nodes in order to acquire lookup data that is needed by the nodes themselves and other nodes for processing instances of input data through a model. The nodes perform the lookups using indices from respective sets of input index vectors from among input index vectors in a full set of input index vectors. FIG. 3 presents a block diagram illustrating a full set of input index vectors and respective sets of input index vectors in accordance with some embodiments. Although a particular number of input index vectors and indices/elements are shown in FIG. 3 as an example, in some embodiments, different numbers of input index vectors and/or indices/elements are used—and the input index vectors and/or indices may be formatted differently. In addition, although a particular number of nodes and embedding tables are used as an example for FIG. 3, in some embodiments, different numbers of nodes and/or embedding tables are used. Generally, the described embodiments are operable with various numbers and arrangements of input index vectors, indices/elements, nodes, and/or embedding tables.

For the example in FIG. 3, an electronic device is assumed to include four nodes, node0-node3, that perform operations for processing instances of input data through a model. As part of these operations, each of the four nodes performs lookups in embedding tables stored in local memories to acquire lookup data that is used by that node itself and by the other nodes for processing instances of input data through model 100. In addition, there are assumed to be twelve embedding tables in total, i.e., embedding tables 0-11, with each node storing a different subset of three of the twelve embedding tables in that node's local memory. More specifically, node0 stores embedding tables 0-2, node1 stores embedding tables 3-5, node2 stores embedding table 6-8, and node3 stores embedding tables 9-11. Each node is further assumed to process five instances of input data through the model. As can be seen via the labels in FIG. 3, node0 processes instances of input data 0-4, node1 processes instances of input data 5-9, node2 processes instances of input data 10-14, and node3 processes instances of input data 15-19.

Processing each instance of input data through the model includes using lookup data acquired from each of the twelve lookup tables as input to specified operations for the model (as described in more detail above). In other words, in order to process an instance of input data through the model, a given node needs a piece of lookup data from each of the twelve lookup tables—the three lookup tables in that node's local memory and the nine lookup tables stored in local memories of other nodes. For example, when processing the first instance of input data (labeled as 0 at the top left of FIG. 3), node0 needs lookup data acquired from indices 9, 2, and 7 of lookup tables 0-2, respectively, which are stored in node0's local memory. Node0 also needs lookup data acquired from indices 0, 2, and 1 of lookup tables 3-5, respectively, which are stored in node1's local memory, lookup data acquired from indices 6, 5, and 4 of lookup tables 6-8, respectively, which are stored in node2's local memory, and lookup data acquired from indices 3, 4, and 5 of lookup tables 9-11, respectively, which are stored in node3's local memory.

The indices to be looked up in each embedding table for processing the instances of input data are included in a corresponding input index vector 302 in the full set of input index vectors 300 (only three input index vectors 302 are labeled in FIG. 3 for clarity). Each input index vector 302 includes an element associated with each instance of input data that stores an index (e.g., a relative or absolute memory address, a pointer, a reference, etc.) where data is to be looked up in the respective embedding table. For example, the first input index vector 302 (labeled 0 at the top left of FIG. 3) includes indices 9, 6, 3, 0, etc. to be looked up in the first embedding table to acquire lookup data for processing respective instances of input data through the model. As another example, the second input index vector (labeled as 1) includes indices 2, 5, 8, 5, etc. to be looked up in the second embedding table to acquire lookup data for processing respective instances of input data through the model.

The four heavier solid-line vertical boxes in FIG. 3 show the division of the input index vectors 302 into four sets in accordance with a node in whose local memory the corresponding embedding tables are stored. For example, the first three input index vectors 302, labeled as 0-2, include indices for embedding tables 0-2, respectively. Embedding tables 0-2 are stored in the local memory in node0 and therefore form a respective set of input index vectors 304 for node0, as shown by a label at the bottom of FIG. 3. As another example, the next three input index vectors 302, labeled as 3-5, are for embedding tables 3-5 stored in the local memory in node1 and therefore form a respective set of input index vectors 306 for node1, as shown by a label at the bottom of FIG. 3. The remaining input index vectors are included in respective sets of input index vectors 308 or 310 for node2 or node3.

When processing instances of input data through the model, each node performs lookups in embedding tables in the local memory in that node using the respective input index vector 302. Each node then either uses the lookup data itself or provides respective portions of the lookup data to other nodes. Generally, for providing respective portions of lookup data to other nodes, each node provides, to each other node, only the lookup data that is needed by that other node. In other words, a given node looks up data in the locally stored embedding tables using the indices from the input index vectors in the respective set of input index vectors and then communicates only the data needed by each other node to that other node via the above-described all-to-all communication. The input indices in each respective set of input index vectors that are used for acquiring lookup data for the node itself and each other node are shown via three heavy dashed horizontal lines in FIG. 3. For example, the indices in respective set of input index vectors 304 for node0 above the top dashed line are used to acquire lookup data for processing instances of input data 0-4 in node0 itself. The lookup data node0 acquires using these indices will therefore not be communicated to another node, but instead will be used in node0. As another example, the indices in respective set of input index vectors 304 for node0 between the top dashed line and the middle dashed line are used to acquire lookup data for processing instances of input data 5-9 in node1. The lookup data node0 acquires using these indices will therefore be communicated from node0 to node1 as part of the all-to-all communication. As yet another example, the indices between the middle dashed line and the bottom dashed line are used to acquire lookup data for processing instances of input data 10-14 in node2. The lookup data node0 acquires using these indices will therefore be communicated from node0 to node2 as part of the all-to-all communication.

The above-described division of the respective sets of input index vectors by the heavier dashed lines divides each respective set of input index vectors into four “parts” (only three parts are labeled in FIG. 3 for clarity). For example, a first part of respective set of input index vectors 310, which includes indices to be used for lookups in node3 for lookup data to be communicated to node0, is labeled as part 312. Part 312 includes all elements of the tenth input index vector from the first through the fifth elements (indexes 3, 7, 8, 9, and 2 of the input index vector labeled 9 in FIG. 3), as well as all elements of the eleventh and twelfth input index vectors from the first through the fifth elements. As another example, part 314 of respective set of input index vectors 310 includes indices to be used for lookups in node3 for lookup data to be communicated to node1 (i.e., for processing instances of input data 5-9 in node1). As yet another example, part 316 of respective set of input index vectors 310 includes indices to be used for lookups in node3 for lookup data to be communicated to node2 (i.e., for processing instances of input data 10-14 in node2). The parts of respective sets of input index vectors are used for compressing lookup data as described in more detail below.

### Overview

In the described embodiments, an electronic device includes a number of nodes communicatively coupled together via a communication fabric. Each of the nodes includes at least one processor and a local memory. For example, in some embodiments, the nodes are or include GPUs, with the processors being GPU cores and the local memories being GPU memories, and the communication fabric being a GPU interconnect to which the GPUs are connected. The nodes (i.e., the processors and memories in the nodes) perform operations for processing instances of input data through a model. For example, in some embodiments, the nodes perform operations for processing instances of input data through a recommendation model such as model 100 as shown in FIG. 1. Processing instances of input data through the model includes using model data for, by, and/or as values for internal elements of the model for performing respective operations. Continuing the model 100 example, the model data includes embedding tables 112 and model data identifying arrangements and characteristics of elements in multilayer perceptrons 106 and 116. At least some of the model data is distributed among the nodes, with separate portions of the model data being stored in the local memory in multiple nodes (i.e., in accordance with model parallelism). Again continuing the model 100 example, individual embedding tables from embedding tables 112 are distributed among multiple nodes, with different embedding tables from among embedding tables 112 being stored in the local memory in each of the multiple nodes. When processing instances of input data through the model, the nodes perform all-to-all communications via the communication fabric to communicate lookup data from rows of embedding tables to one another. The described embodiments perform operations for compressing the lookup data communicated from node to node when processing instances of input data through the model. In other words, the described embodiments perform operations for reducing an amount of lookup data that is communicated from node to node when processing the instances of input data through the model.

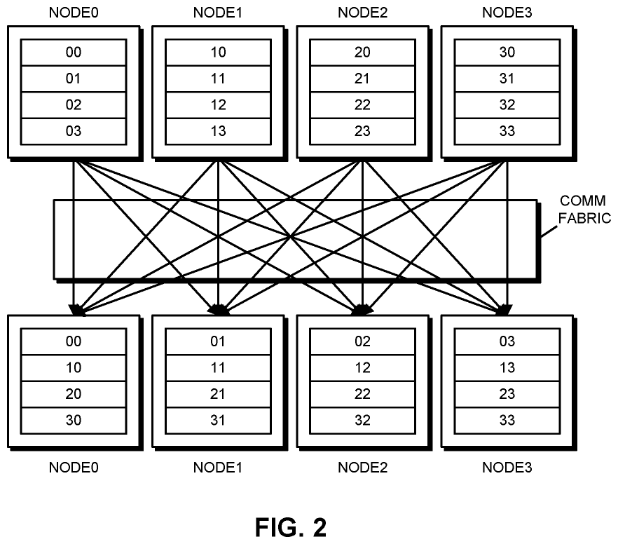

For “compressing” the lookup data communicated between the nodes, the described embodiments avoid communicating duplicated lookup data that would be communicated between the nodes in existing electronic devices. Generally, duplicated lookup data includes two or more pieces of lookup data that match one another. The described embodiments identify duplicated lookup data that would otherwise be communicated between the nodes and perform operations for preventing duplicated lookup data from being communicated between the nodes. For this operation, when processing instances of input data through the model, each node receives or acquires a respective set of input index vectors (e.g., respective set of input index vectors 310) having a number of parts (e.g., part 312). Each node processes each of the parts to identify duplicate input indices in the input index vectors in that part, i.e., input indices that match other input indices elsewhere in the elements of each input index vector that are included within that part. Each node removes duplicate input indices from each input vector in each part to generate a compressed set of input index vectors for that part. In this way, each node generates a compressed set of input index vectors for each part with duplicate input indices removed. Each node then uses the compressed set of input index vectors for each part for performing lookups for acquiring lookup data from the embedding table(s) stored in the local memory in that node. Each node locally uses the lookup data acquired using the indices from one of the parts for processing instances of instance of input data. Each node communicates the lookup data acquired using the compressed set of input index vectors for each remaining part, i.e., compressed lookup data for that part, to a corresponding other node in an all-to-all communication (such as shown in FIG. 2). Because the nodes perform lookups using the compressed set of input index vectors for each part, the nodes do not perform lookups for the removed duplicate input indices. This reduces the number of lookups performed by the nodes and thus the information from the respective embedding tables communicated from the nodes in the all-to-all communication. This reduction in the number of lookups, and therefore amount of lookup data communicated between the nodes, is the compression of the lookup data described herein.

In some embodiments, for generating the compressed set of input index vectors as described above, each node first receives or acquires a respective set of input index vectors with a number of parts. Each node then processes input index vectors in each of the parts to identify duplicate input indices in the input index vectors. For example, in some embodiments, each node identifies unique input indices in the elements of each input vector in each of the parts. The unique input indices are first appearances of input indices that are subsequently duplicated one or more times within the elements of a given input index vector in a part—as well as input indices that appear only once in a given input index vector in the part. Each node then identifies locations of input indices in the elements of each input vector in each part that are duplicates of unique input indices in that input index vector. Each node then generates the compressed set of input index vectors for each part by removing duplicate input indices from each input index vector for that part—leaving only unique input indices in the input index vectors in the compressed set of input index vectors for each part. Each node then uses the compressed set of input index vectors for each of the parts of the respective set of input index vectors to perform lookups in the embedding tables stored in the local memory to generate compressed lookup data as described above.

Along with generating the compressed set of input index vectors for each part of the respective set of input index vectors, each node produces a record of locations of duplicate input index indices for each part. Generally, the record of locations of duplicate input indices for each part identifies locations from where input indices were removed from input index vectors in that part when generating the compressed set of input index vectors for that part. Using the information in the records of duplicate input indices, the original/uncompressed input index vectors in each part can be regenerated from the compressed set of input index vectors for that part. In addition, and as described in more detail below, the information in the record of locations of duplicate input index indices for each part can be used to generate decompressed lookup data from compressed lookup data that was acquired using the compressed set of input index vectors for that part. For producing the record of locations of duplicate input index indices for each part, each node produces a record that identifies: (1) locations of unique input indices in each input index vector in the compressed set of input index vectors for that part, (2) locations of removed input indices that are duplicates of the unique input indices in each input index vector in that part, and (3) a number of indices in the input index vectors in the compressed set of input index vectors for that part. After generating a record of locations of duplicate input indices for each part, the node communicates that record to a corresponding other node—i.e., to an other node that is to use that record for decompressing compressed lookup data as described herein.

In some embodiments, although lookup data is compressed for the all-to-all communication between the nodes, the compressed lookup data is eventually decompressed by a receiving node for use in subsequent operations (i.e., for use in operations that rely on the lookup data that is not present in the compressed lookup data). For this operation, a sending node first generates compressed lookup data for a part of a respective set of input index vectors using a compressed set of input index vectors for the part as described above. The sending node then generates and communicates a record of locations of duplicate input index indices for the part to a given node and separately communicates the compressed lookup data for the part to the given node in an all-to-all communication as described above. The given node sets aside/generates a buffer for storing the compressed lookup data based on a size of the data value associated with the compressed lookup data (e.g., included in or with the record of locations of duplicate input index indices). The given node then receives the compressed lookup data for the part, which is stored in the buffer, and decompresses the compressed lookup data for the part to generate decompressed lookup data for the part. For this operation, the given node identifies locations of missing duplicate lookup data in the compressed lookup data for the part using the record of locations of duplicate input indices for the part. The given node then copies the missing duplicate lookup data from locations in the compressed lookup data for the part to the locations. During the decompression operation, therefore, the given node creates the full lookup data for the part that would have been generated by the sending node had the sending node performed lookups using all of the indices in the part of the respective set of input index vectors (instead of using the compressed set of input index vectors for the part). The given node combines similar decompressed lookup data from all other nodes to produce the full lookup data used for processing instances of input data through the model. Because the lookup data in the compressed lookup data is sufficient to create the full lookup data using the record of duplicate input indices, the compression of the lookup data is “lossless.” That is, all data needed for creating the full lookup data can be found in the compressed lookup data.

By using the compressed sets of input index vectors for performing lookups in embedding tables to generate compressed lookup data, the described embodiments reduce the number of lookups that are performed in each of the nodes for acquiring the lookup data (in contrast to existing electronic devices, which use the full lookup data). This reduces the operational load on the nodes and the local memories in the nodes. In addition, by communicating compressed lookup data from node to node, the described embodiments reduce the amount of data communicated on the communication fabric and reduce the latency for operations of the nodes that rely on the lookup data (in contrast to existing electronic devices that communicate the full lookup data). This renders the nodes and the communication fabric more available for performing other operations, which can increase the performance of the nodes and the communication fabric. Increasing the performance of the nodes or the communication fabric increases the performance of the electronic device, which increases user satisfaction with the electronic device.

### Electronic Device

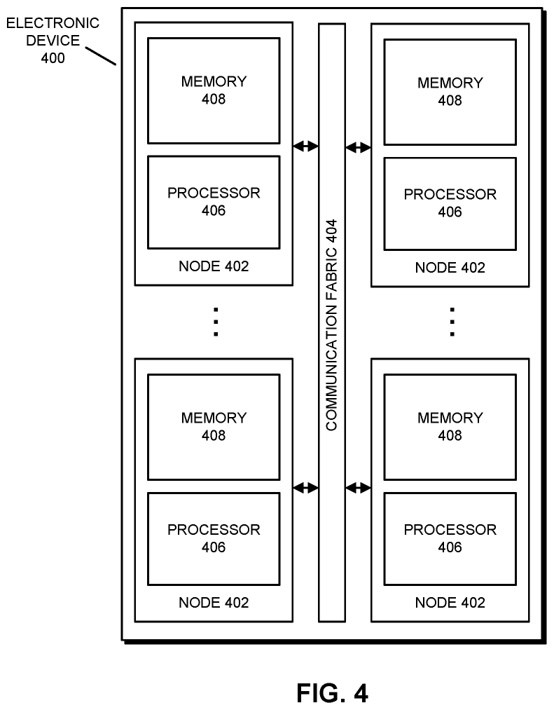

FIG. 4 presents a block diagram illustrating electronic device 400 in accordance with some embodiments. As can be seen in FIG. 4, electronic device 400 includes a number of nodes 402 connected to a communication fabric 404. Nodes 402 and communication fabric 404 are implemented in hardware, i.e., using corresponding integrated circuitry, discrete circuitry, and/or devices. For example, in some embodiments, nodes 402 and communication fabric 404 are implemented in integrated circuitry on one or more semiconductor chips, are implemented in a combination of integrated circuitry on one or more semiconductor chips in combination with discrete circuitry and/or devices, or are implemented in discrete circuitry and/or devices. In some embodiments, nodes 402 and communication fabric 404 perform operations for or associated with compressing lookup data that is communicated by nodes 402 as described herein.

Each node 402 includes a processor 406. The processor 406 in each node 402 is a functional block that performs computational, memory access, and/or other operations (e.g., control operations, configuration operations, etc.). For example, each processor 406 can be or include a graphics processing unit (GPU) or GPU core, a central processing unit (CPU) or CPU core, an accelerated processing unit (APU), a system on a chip (SOC), a field programmable gate array (FPGA), and/or another form of processor.

Each node 402 includes a memory 408 (which can be called a “local memory” herein). The memory 408 in each node 402 is a functional block that performs operations for storing data for accesses by the processor 406 in that node 402 (and possibly processors 406 in other nodes). Each memory 408 includes volatile and/or non-volatile memory circuits for storing data, as well as control circuits for handling accesses of the data stored in the memory circuits, performing control or configuration operations, etc. For example, in some embodiments, the processor 406 in each node 402 is a GPU or GPU core and the respective local memory 408 is or includes graphics memory circuitry such as graphics double data rate synchronous DRAM (GDDR). As described herein, the memories 408 in some or all of the nodes 402 store embedding tables and other model data for use in processing instances of input data through a model (e.g., model 100).

Communication fabric 404 is a functional block and/or device that performs operations for or associated with communicating data between nodes 402. Communication fabric 404 is or includes wires, guides, traces, wireless communication channels, transceivers, control circuits, antennas, and/or other functional blocks and devices that are used for communicating data. For example, in some embodiments, nodes 402 are or include GPUs and communication fabric 404 is a graphics interconnect and/or other system bus. In some embodiments, compressed lookup data and records of duplicate input indices are communicated from node 402 to node 402 via communication fabric 404 as described herein.

Although electronic device 400 is shown in FIG. 4 with a particular number and arrangement of functional blocks and devices, in some embodiments, electronic device 400 includes different numbers and/or arrangements of functional blocks and devices. For example, in some embodiments, electronic device 400 includes a different number of nodes 402. In addition, although each node 402 is shown with a given number and arrangement of functional blocks, in some embodiments, some or all nodes 402 include a different number and/or arrangement of functional blocks. Generally, electronic device 400 and nodes 402 include sufficient numbers and/or arrangements of functional blocks to perform the operations herein described.

Electronic device 400 and nodes 402 are simplified for illustrative purposes. In some embodiments, however, electronic device 400 and/or nodes 402 include additional or different functional blocks, subsystems, elements, and/or communication paths. For example, electronic device 400 and/or nodes 402 may include display subsystems, power subsystems, input-output (I/O) subsystems, etc. Electronic device 400 generally includes sufficient functional blocks, subsystems, elements, and/or communication paths to perform the operations herein described. In addition, although four nodes 402 are shown in FIG. 4, in some embodiments, a different number of nodes 402 is present (as shown by the ellipses in FIG. 4).

Electronic device 400 can be, or can be included in, any device that can perform the operations described herein. For example, electronic device 400 can be, or can be included in, a desktop computer, a laptop computer, a wearable computing device, a tablet computer, a piece of virtual or augmented reality equipment, a smart phone, an artificial intelligence (AI) or machine learning device, a server, a network appliance, a toy, a piece of audio-visual equipment, a home appliance, a vehicle, and/or combinations thereof. In some embodiments, electronic device 400 is or includes a circuit board or other interposer to which multiple nodes 402 are mounted or connected and communication fabric 404 is an inter-node communication route. In some embodiments, electronic device 400 is or includes a set or group of computers (e.g., a group of server nodes in a data center) and communication fabric 404 is a wired and/or wireless network that connects the nodes 402. In some embodiments, electronic device 400 is included on one or more semiconductor chips. For example, in some embodiments, electronic device 400 is entirely included in a single “system on a chip” (SOC) semiconductor chip, is included on one or more ASICs, etc.

### Compressed Input Index Vectors and Records of Duplicate Input Indices

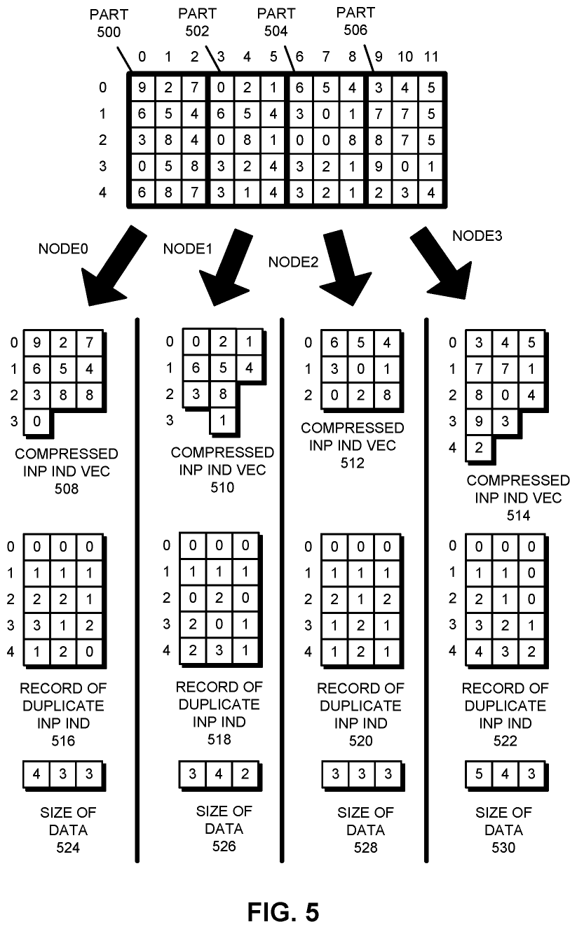

In the described embodiments, nodes in an electronic device perform operations for compressing lookup data. Generally, for this operation, the nodes generate compressed sets of input index vectors for parts of respective sets of input index vectors that are used for acquiring lookup data from embedding tables. Because the data is acquired from the lookup tables using compressed sets of input index vectors, the acquired lookup data, i.e., compressed lookup data, includes less lookup data than would be present if the full respective sets of input index vectors were used for acquiring the lookup data. The nodes also generate records of duplicate input indices that identify indices that were removed from the input index vectors during the compression operations. The records of duplicate input indices can be used for operations including decompressing corresponding compressed lookup data. FIG. 5 presents a block diagram illustrating the generation of compressed sets of input index vectors and records of duplicate input indices in accordance with some embodiments. FIG. 5 is presented as a general example of operations performed in some embodiments. In other embodiments, however, different operations are performed and/or operations are performed in a different order. Additionally, although certain elements are used in describing the process, in some embodiments, other elements perform the operations.

For the example in FIG. 5, assumptions similar to the assumptions made for the example in FIG. 3 are made. That is, there are assumed to be four nodes, node0-node3. There are also assumed to be twelve embedding tables in total, i.e., embedding tables 0-12, and each node stores, in that node's local memory, a different subset of three of the twelve embedding tables in that node's local memory (i.e., node0 stores embedding tables 0-2, node1 stores embedding tables 3-5, etc.). Each node is additionally assumed to process five instances of input data through the model, with node0 processing instances of input data 0-4, node1 processing instances of input data 5-9, etc.

For the example in FIG. 5 it is assumed that a full set of input index vectors to be used for processing instances of input data through a model includes the same indices as full set of input index vectors 300. For the operations in FIG. 5, however, only indices to be used for acquiring lookup data to be used by node0 are addressed—and the indices shown in FIG. 5 therefore match the indices shown above the top heavier dashed line in FIG. 3. In other words, only operations involving a part of each respective input index vector for each of nodes0-3 that includes indices for acquiring lookup data for node0 are described. In some embodiments, however, similar operations are performed for generating the compressed sets of input indices and records of duplicate input indices for nodes1-3. That is, compressed sets of input index vectors and records of duplicate input indices are also generated for each other part of the respective sets of input index vectors, although this is not shown in FIG. 5 for clarity and brevity.

As can be seen in FIG. 5, the parts the full set of input index vectors include parts 500-506. As described above, each of parts 500-506 includes a portion of the input index vectors with indices to be looked up by a corresponding node from among nodes0-3 for lookup data to be used by node0 for processing instances of input data 0-4 through the model. More specifically, part 500 includes indices to be looked up by node0, part 502 includes indices to be looked up by node1, part 504 includes indices to be looked up by node2, and part 506 includes indices to be looked up by node3. Using part 502 as an example, the indices in the elements of the fourth input vector (labeled 3 in FIG. 5) are to be looked up by node1 in embedding table 3, the indices in the elements of the fifth input vector (labeled 4) are to be looked up by node1 in embedding table 4, and the indices in the elements of the sixth input vector (labeled 5) are to be looked up by node1 in embedding table 5.

The operations in FIG. 5 start when each node receives or acquires the parts of the respective set of input index vectors (i.e., receives the respective set of input index vectors including the parts), with node0 receiving or acquiring part 500, node1 receiving or acquiring part 502, etc. Each node then generates a compressed set of input index vectors from that node's part—i.e., generates compressed sets of input index vectors (COMPRESSED INP IND VEC) 508-514, respectively. For this operation, each node identifies unique input indices in each input index vector that node's part (i.e., in the elements of each input index vector included in that node's part). The node also identifies input indices in each input index vector in that node's part that are duplicates of unique input indices in that input index vector. For example, for processing part 502, node1 identifies unique indices 0, 6, and 3 in the first input index vector in part 502 (labeled 3 at the top of FIG. 5); identifies unique indices 2, 5, 8, and 1 in the second input vector (labeled 4); and identifies unique indices 1 and 4 in the third index vector in part 502 (labeled 5). Node1 also identifies the second instances of indices 0 and 3 in the first input index vector in part 502 as duplicates, identifies the second instance of index 2 in the second input index vector in part 502 as a duplicate, and identifies the second instance of the index 1 and the second and third instances of index 4 in the third index vector in part 502 as duplicates. In other words, based on the occurrence of a previous matching index in their particular input index vector, node1 identifies each of these indices as duplicates within their particular input index vector. The nodes then generate a respective compressed set of input index vectors by removing duplicate input indices from input index vectors in that node's part—and moving the remaining input indices to create a block of indices in the compressed set of input index vectors. Continuing with the example using part 502, node1 removes the duplicated indices of 0 and 3 from the first input index vector and moves the first/unique instance of index 3 upward, removes the duplicated index of 2 from the second input index vector and shifts the first/unique instance of index 1 upward, and removes the duplicated indices of 1 and 4 from the third input index vector. The resulting compressed set of input index vectors 510 for node1 is shown in the second column, as indicated by the arrow from part 502. As can be seen in compressed set of input index vectors 510, the input index vectors, which each previously included five elements/indices, now include only three elements/indices, in the case of the first input index vector, four elements/indices, in the cases of the second input index vector, and two elements/indices, in the case of the third input index vector. This is the “compression” of the input index vectors from part 502. The other nodes perform similar operations for generating compressed set of input index vectors 508 and 512-514 from parts 500 and 504-506, as indicated by the arrows in FIG. 5. Note that, in some cases, a given input index vector in the part does not include any duplicated indices and thus the compression operation does not change the given input index vector. This is shown by the first input index vector in compressed set of input index vectors 514, which includes all of the same indices as the first input index vector in part 506 (labeled as 9).

Each node also generates a record of duplicate input indices. For this operation, each node creates a record that can be used for identifying locations from where indices were removed from input index vectors in the corresponding part when generating the compressed set of input index vectors. Generally, each record of duplicate input indices includes information for identifying locations of unique input indices in each input index vector in the compressed set of input index vectors for the corresponding part, as well as for identifying locations of removed input indices that are duplicates of the unique input indices in each input index vector for that part. In some embodiments, the records of the duplicate input indices are arranged shown in records of duplicate input indices (RECORD OF DUPLICATE INP IND) 516-522, with each location in the record associated with a location in the part (i.e., having a one-to-one correspondence with elements that were present in the part of the respective set of input index vectors). In these embodiments, each element in the record of duplicated input indices includes a reference to a location of a unique index in the compressed set of input index vectors. Continuing the example from part 502, a first column in the record of duplicate input indices 518 has 0s in the first and third elements, which identifies that the index in the first input index vector in part 502 that was originally found in the first and third locations of the first input index vector in part 502 can now be found in the first element of the first input index vector in compressed set of input index vectors 510. In other words, record of duplicate input indices 518 indicates that, in the original state of part 502, the index in the first and third elements matched (the second instance was removed during the compression as described above). In addition, a first column in the record of duplicate input indices has a 1 in the second element, which identifies that the index in the first input index vector in part 502 that was originally found in the second location of the first input index vector in part 502 can now be found in the second element of the first input index vector in compressed set of input index vectors 510. Also, a first column in the record of duplicate input indices has 2s in the fourth and fifth elements, which identify that the index in the first input index vector in part 502 that was originally found in the fourth and fifth locations of the first input index vector in part 502 can now be found in the third element of the first input index vector in compressed set of input index vectors 510. In other words, the record of duplicate input indices indicates that, in the original state of part 502, the index in the fourth and fifth elements of the first input vector matched. The first instance of the index 3 was moved from the fourth location during the compression and the second instance of the index was removed during the compression as described above.

Each node also separately generates a size of the data and includes the size of the data in or with the record of duplicate input indices. Examples of sizes of the data are shown as size of the data (SIZE OF DATA) 524-530 for each of parts 500-506, respectively, in FIG. 5. Generally, each of the sizes of the data includes values that can be used by a receiving node for determining amounts of lookup data in compressed lookup data that were generated using input index vectors in corresponding compressed sets of input index vectors. Including the size of the data therefore helps the receiving node determine the amount of lookup data that is present, given that the amount of lookup data acquired using each different input index vector in compressed sets of input index vectors can be different. In some embodiments, a receiving node uses the size of the data for allocating an appropriately sized receive buffer for receiving/storing the respective compressed lookup data. Continuing the example using part 502, size of data 526 is a vector that includes an element/location associated with each individual input index vector in compressed input index vectors 510. Each of the elements/locations in size of data 526 stores a value indicating the number of indices present in a respective input index vector in the compressed set of input index vectors 510. For example, as shown in the leftmost element in size of the data 526, the leftmost input index vector in compressed input index vectors 510 includes four input indices—and thus the resulting lookup data will include four pieces of lookup data.

### Compressing and Decompressing Lookup Data

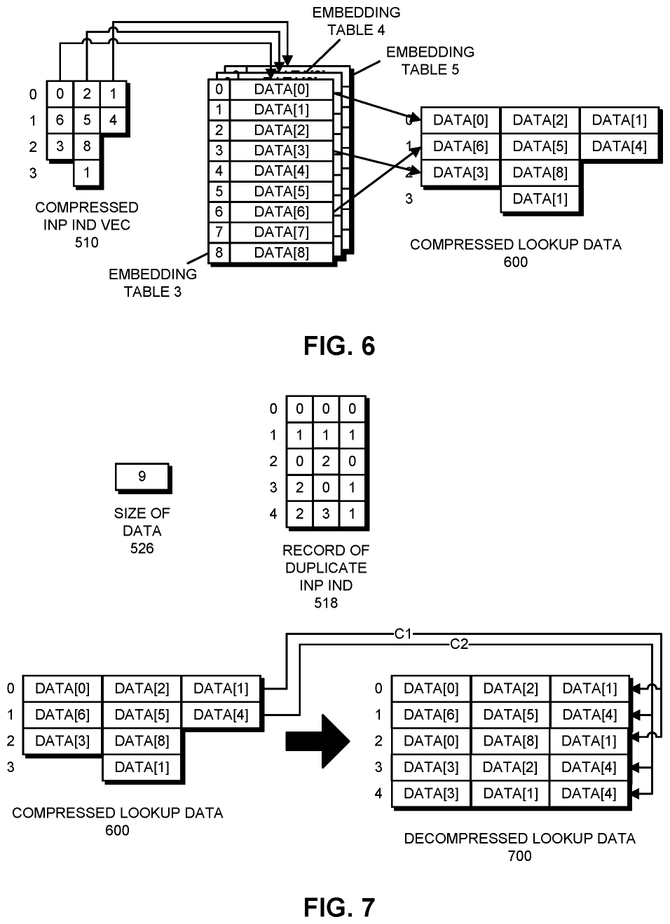

In the described embodiments, nodes perform operations for decompressing compressed lookup data received from other nodes. Generally, for this operation, when processing instances of input data through a model, each node receives, from the other nodes, compressed lookup data that was generated using a compressed set of input index vectors. The nodes decompress the compressed lookup data using a record of duplicate input indices to generate decompressed data that is then used for subsequent operations for processing instances of input data though the model. FIG. 6 presents a block diagram illustrating operations for generating compressed lookup data in accordance with some embodiments. FIG. 7 presents a block diagram illustrating operations for decompressing compressed lookup data in accordance with some embodiments. FIGS. 6-7 are presented as general examples of operations performed in some embodiments. In other embodiments, however, different operations are performed and/or operations are performed in a different order. Additionally, although certain elements are used in describing the process, in some embodiments, other elements perform the operations

For the examples in FIGS. 6-7, assumptions similar to the examples in FIGS. 3 and 5 are made. That is, there are assumed to be four nodes, node0-node3. There are also assumed to be twelve embedding tables in total, i.e., embedding tables 0-12, and each node stores, in that node's local memory, a different subset of three of the twelve embedding tables in that node's local memory (i.e., node0 stores embedding tables 0-2, node1 stores embedding tables 3-5, etc.). Each node is additionally assumed to process five instances of input data through the model, with node0 processing instances of input data 0-4, node1 processing instances of input data 5-9, etc.

For the example in FIGS. 6-7 it is assumed that a full set of input index vectors to be used for processing instances of input data through a model includes the same indices as full set of input index vectors 300. It is also assumed that the operations of FIG. 5 have been performed for generating the corresponding compressed input index vectors and the records of duplicate input indices. Only one of the compressed set of input indices and records of duplicate input indices are shown and described in FIGS. 6-7, however, for clarity and brevity. Specifically, compressed set of input index vectors 510 to be processed in node1 and the corresponding record of duplicate input indices 518 are used as an example. In some embodiments, however, similar operations are performed for compressing and decompressing lookup data using other compressed sets of input index vectors and records of duplicate input indices. That is, compressed lookup data is generated using the compressed sets of input indices for each of nodes0-3 and corresponding records of duplicate input indices are used for decompressing the compressed lookup data. To be clear, therefore, each node processes each part of a respective set of input index vectors to generate compressed sets of input index vectors associated with each other node. That node then uses each of the compressed sets of input index vectors to acquire, from the corresponding embedding tables, compressed lookup data. That node also generates and communicates respective records of duplicate input indices to each other node. The node next communicates compressed lookup data to each other node during the all-to-all communication. The other nodes next use the respective records of duplicate input indices to decompress compressed lookup data. Each node therefore generates and communicates compressed lookup data to each other node—and the other nodes decompress the compressed lookup data using the appropriate records of duplicate input indices similar to what is shown in FIGS. 6-7.

The operations in FIG. 6 start when node1 generates compressed set of input index vectors 510 for part 502 as described above. Node1 then performs lookups in embedding table 3 (i.e., from among embedding tables 3-5 stored in the local memory of node1) for the indices in the first input vector in compressed set of input index vectors 510. For this operation, node1 acquires data from embedding table 3 for indices 0, 6, and 3. Node1 writes the lookup data acquired from embedding table 3 to compressed lookup data 600. This is illustrated via the arrows between the corresponding locations in embedding table 3 and the first column of compressed lookup data 600. Node1 also performs lookups to acquire lookup data from embedding tables 4 and 5, respectively, for the indices in the second and third input index vectors in compressed set of input index vectors 510. As with the lookup data acquired from embedding table 3, node1 writes the lookup data acquired from embedding tables 4-5 to the second and third columns, respectively, in compressed lookup data 600 (although arrows are not shown for these writes for clarity). After these operations are complete, compressed lookup data 600 includes the data shown in FIG. 6, i.e., includes data from the respective embedding table located at the identified index (i.e., index 0 for DATA[0], etc.).

After generating compressed lookup data 600, node1 communicates compressed lookup data 600 to node0 in an all-to-all communication (recall that node0 is the node processing the corresponding instances of input data). Before communicating compressed lookup data 600 to node0, however, node1 communicates record of duplicated input indices 518 and size of the data 526 to node0. Receiving size of data 526 in advance of compressed lookup data 600 enables node0 to determine the size/amount of data in compressed lookup data 600 for operations such as reserving receiver buffer space for storing compressed lookup data 600, etc.

The operations in FIG. 7 start when node0 receives size of the data 526 and record of duplicate input indices 518, which node0 stores for future use, as described above for FIG. 6. Node0 then subsequently receives compressed lookup data 600 via the all-to-all communication from node1, as also described above for FIG. 6. Node0 next performs operations for decompressing compressed lookup data 600. For these operations, node0 uses record of duplicate input indices 518 to determine where duplicate input indices were removed when generating compressed set of input index vectors 510—and thus indices that were not used for performing lookups in embedding tables 3-5 when generating compressed lookup data 600. In other words, node0 uses record of locations of duplicate input indices 518 to determine which lookups node1 skipped and therefore what data is missing from compressed lookup data 600, thereby identifying locations of missing duplicate lookup data in compressed lookup data 600. Node0 then generates decompressed lookup data 700 by copying missing duplicate lookup data from locations in the compressed lookup data 600 to the identified locations. For example, some of the copy operations performed by node0 are illustrated for the right column of decompressed lookup data 700 (similar operations can be performed for the other two columns). As shown via a first copy operation (C1), node0 copies data[1] i.e., lookup data from index 1 of embedding table 5, from the first location in the right column of compressed lookup data 600 to the first and third locations in the right column of decompressed lookup data 700. As shown via a second copy operation (C2), node0 copies data[4] from the second location in compressed lookup data 600 to the second, fourth, and fifth locations in the right column of decompressed lookup data 700. When this operation is completed, node0 has some of the decompressed lookup data to be used for subsequent operations for processing instances of input data through the model. In some embodiments, the decompressed data is further processed, e.g., in an accumulation operation, etc., as part of the subsequent operations for processing instances of input data through the model.

Although a particular compressed set of input index vectors, embedding tables, compressed lookup data, record of duplicate input indices, size of the data, and decompressed lookup data are shown in FIGS. 6-7, these are merely examples. In some embodiments, the compressed set of input index vectors, embedding tables, compressed lookup data, record of duplicate input indices, size of the data, and/or decompressed lookup data are arranged differently, include different numbers of elements, and/or are otherwise different. Generally, in some embodiments, nodes perform operations similar to those shown above for handling lookup data for processing instances of input data through a model.

### Compressed Lookup Data and Model Operations

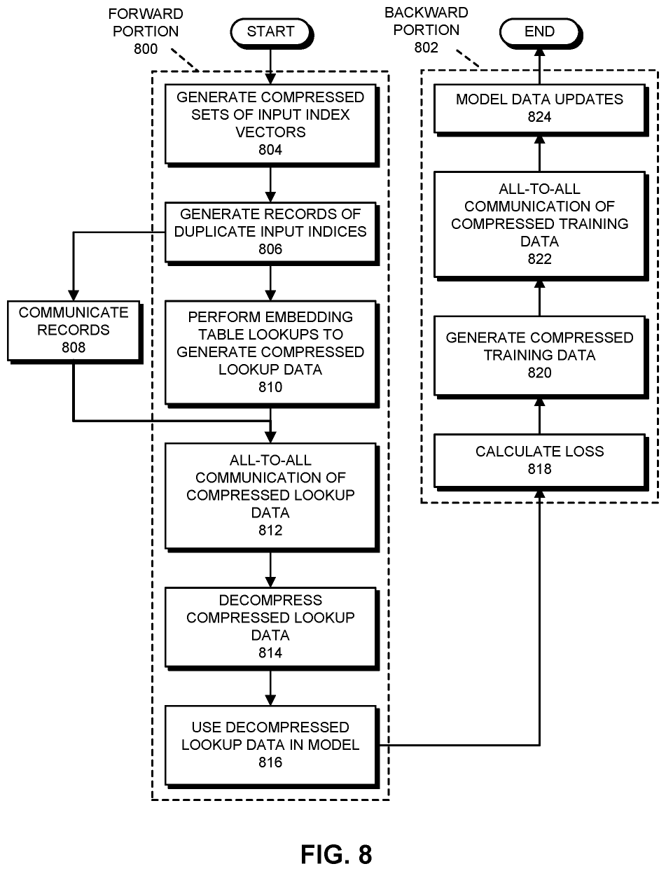

In the described embodiments, lookup data is compressed in order to avoid the need for communicating full lookup data between nodes during an all-to-all communication while processing instances of input data through a model. FIG. 8 presents a flowchart illustrating operations for processing instances of input data through a model using compressed lookup data in accordance with some embodiments. FIG. 8 is presented as a general example of operations performed in some embodiments. In other embodiments, however, different operations are performed and/or operations are performed in a different order. Additionally, although certain elements are used in describing the process, in some embodiments, other elements perform the operations.

For the operations in FIG. 8, a training process is shown for model 100. In other words, during the operations shown in FIG. 8, model 100 is trained in order to prepare model 100 for subsequent inference operations. Generally, training involves an iterative scheme during which, for forward portion 800, instances of input data having expected outputs are processed through model 100 to generate actual outputs. In some embodiments, forward portion 800 is an inference portion of the training—and therefore involves operations that model 100 will perform during inference operations for generating inference results after the training is completed. For backward portion 802, error/loss values are computed based on the actual outputs from the model versus expected outputs for the model for the instances of input data and the error/loss values are backpropagated through the model to update (i.e., adjust, correct, etc.) model data. During backward portion 802 as shown in FIG. 8, model data including embedding table values in embedding tables 112 is updated (and is compressed before being communicated from node to node). The specific operations performed during backward portion 802 involve operations such as gradient descent, etc. that are known in the art and are not described in detail herein for clarity and brevity.

For the example in FIG. 8, assumptions similar to the assumptions made for the example in FIGS. 3 and 5-7 are made. That is, there are assumed to be four nodes, node0-node3. There are also assumed to be twelve embedding tables in total, i.e., embedding tables 0-12, and each node stores, in that node's local memory, a different subset of three of the twelve embedding tables in that node's local memory (i.e., node0 stores embedding tables 0-2, node1 stores embedding tables 3-5, etc.). Each node is additionally assumed to process five instances of input data through the model, with node0 processing instances of input data 0-4, node1 processing instances of input data 5-9, etc.

The operations shown in FIG. 8 start when the nodes generate compressed sets of input index vectors from respective sets of input index vectors (step 804). For this operation, each node generates, for each part (e.g., part 312, etc.) of the respective set of input index vectors a compressed set of input index vectors (e.g., compressed set of input index vectors 508, etc.). Each node also generates corresponding records of duplicate input indices (step 806). For example, in some embodiments, for each part of the respective set of input index vectors, the nodes can perform operations for generating the compressed set of input index vectors and record of duplicate input indices similar to those described for FIG. 5.

The nodes then communicate the records of duplicate input indices to corresponding other nodes (step 808). Recall that, in some embodiments, the records include size of data information (e.g., size of the data 524, etc.) that is subsequently used by a receiving node for determining a size of compressed input data to be received from the node that sent the record of the duplicate input indices. The nodes therefore send the records of duplicate input indices prior to the all-to-all communication in step 812 (and possibly substantially in parallel with performing embedding table lookups in step 810) so that the receiving nodes will be able to process received compressed lookup data.

The nodes then use the compressed sets of input index vectors to perform embedding table lookups for generating compressed lookup data (step 810). For this operation, for input index vectors (or elements thereof) in the compressed set of input index vectors for each part of the respective set of input index vectors, each node looks up data in the corresponding embedding table. The nodes generate corresponding compressed lookup data using lookup data acquired during the lookups. For example, in some embodiments, for each compressed set of input index vectors, each node performs operations similar to those shown in FIG. 6 for generating the respective compressed lookup data.

The nodes then perform an all-to-all communication of the compressed lookup data (step 812). For this operation, the nodes communicate the compressed lookup data for each other node to that other node in an operation similar to that shown in FIG. 2.

The nodes receive the compressed lookup data from each other node (i.e., each node receives compressed lookup data from three other nodes) and perform operations for decompressing the compressed lookup data (step 814). For this operation, the nodes use the respective record of duplicate input indices to identify locations of missing lookup data in the compressed lookup data received from each other node and copy the missing lookup data to the locations in preparation for using the decompressed lookup data in subsequent operations for processing instances of input data through the model. For example, in some embodiments, the nodes can perform operations similar to those shown in FIG. 7 for decompressing the compressed lookup data received from each other node.

The nodes then use the decompressed lookup data for processing instances of input data through the model (step 816). For example, in some embodiments, the nodes use the decompressed lookup data as input to combination 114, where the decompressed lookup data is combined with output from multilayer perceptron 106 to prepare input data for multilayer perceptron 116. Step 816 is the last operation of the forward portion 800, and so a model output 118 is generated during/as a result of step 816. For example, during step 816, the nodes can generate ranked lists of items from among a set of items to be presented to users as recommendations, probabilities that a particular user will click on/select a given item if presented with the item, and/or other outputs.

The nodes then commence operations for backward portion 802, i.e., for using the output from model 100 to update/train the model. The nodes therefore calculate a loss based on the output from the model (step 818). The nodes then use the record that identifies locations of duplicate input indices (from steps 806-808) to generate compressed training data (step 820). For this operation, the nodes remove training data based on the locations of duplicated input indices from the full set of training data, thereby reducing the size of the training data. The nodes then send the compressed training data (i.e., corresponding portions of the compressed training data) to all the other nodes using an all-to-all communication (step 822). The other nodes use the compressed training data to make model data updates (step 824). The model data updates include updates to the embedding tables stored in the local memory in the nodes—and to other model data, such as parameters for the multilayer perceptrons, etc. The other nodes therefore use the compressed data to compute/determine model data updates and then write the updates to the embedding tables. For this operation, the use of the compressed training data (i.e., without decompressing the training data) is functionally correct due to the duplicative nature of training data that is removed from the compressed training data.

In some embodiments, as part of using the decompressed lookup data in the model (step 816), the nodes perform operations for preparing the decompressed lookup data for being used in the model. For example, in some embodiments, the nodes perform accumulation operations on decompressed lookup data in order to combine and/or reduce the lookup data. For instance, the nodes can perform mathematical, bitwise, logical, and/or other operations on portions of the decompressed lookup data (e.g., data from individual rows of the embedding table) in order to combine the portions of the decompressed lookup data.

Although a training process having a forward portion 800 and a backward portion 802 is presented as an example in FIG. 8, in some embodiments, only the forward portion 800 of the process is performed by the node and the nodes. For example, after a training operation is complete—and thus the model is judged to be ready for inference operations—the node and nodes can perform inference operations via the operations shown in forward portion 800.

### Process for Generating a Compressed Lookup Data

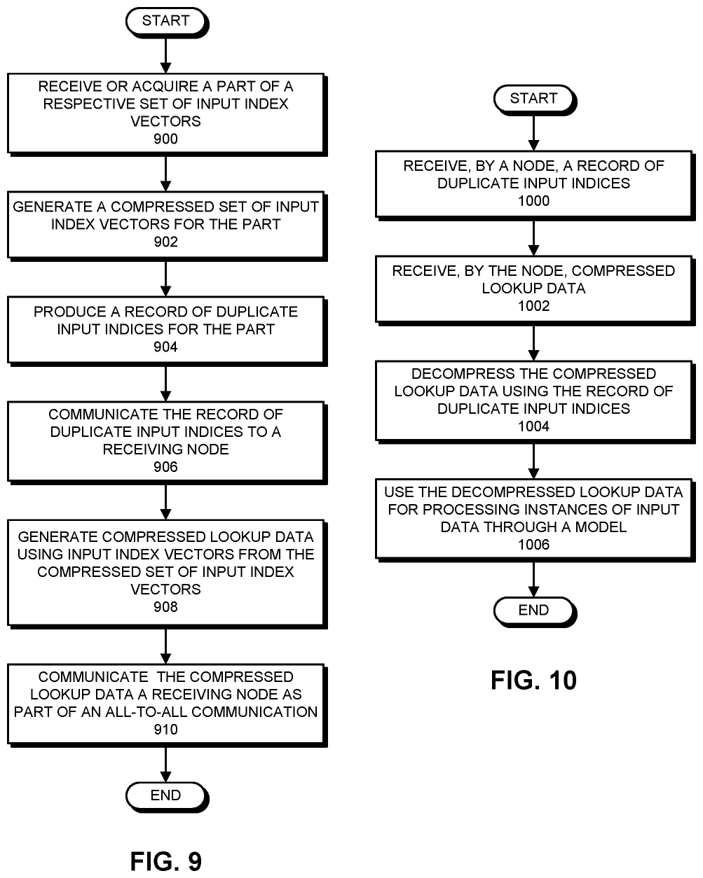

In the described embodiments, a node performs operations for compressing lookup data that is to be communicated to other nodes for processing instances input data through a model. Generally, these operations include generating compressed sets of input index vectors for parts of respective sets of input index vectors (e.g., parts 312-316 of respective set of input vector 310, etc.) so that nodes can perform a smaller numbers of lookups in embedding tables stored in local memories in the nodes—and can therefore generate less lookup data to be communicated to other nodes. FIG. 9 presents a flowchart illustrating a process for generating compressed lookup data in accordance with some embodiments. FIG. 9 is presented as a general example of operations performed in some embodiments. In other embodiments, however, different operations are performed and/or operations are performed in a different order. Additionally, although certain elements are used in describing the process, in some embodiments, other elements perform the operations.

For the example in FIG. 9, assumptions similar to the assumptions made for the example in FIGS. 3 and 5-8 are made. That is, there are assumed to be four nodes, node0-node3. There are also assumed to be twelve embedding tables in total, i.e., embedding tables 0-12, and each node stores, in that node's local memory, a different subset of three of the twelve embedding tables in that node's local memory (i.e., node0 stores embedding tables 0-2, node1 stores embedding tables 3-5, etc.). Each node is additionally assumed to process five instances of input data through the model, with node0 processing instances of input data 0-4, node1 processing instances of input data 5-9, etc.

For the example in FIG. 9, operations similar to those performed in FIGS. 5-6 are presented in flowchart form. Similarly to FIG. 5-6, for the example in FIG. 9, it is assumed that a full set of input index vectors to be used for processing instances of input data through a model includes the same indices as full set of input index vectors 300. For the operations in FIG. 9, however, operations are described for generating a compressed lookup data for only one part of the full set of input index vectors (e.g., part 312, etc.). In some embodiments, a corresponding node performs similar operations for generating compressed lookup data for each part of the full set of input index vectors. For example, node3 can perform similar operations for each of parts 312-316—along with the unlabeled part in respective set of input index vectors 310.

The operations in FIG. 9 start when a node receives or acquires a part of a respective set of input index vectors that includes a part (step 900). For this operation, the node can receive a part such as part 312 in FIG. 3. The node then generates a compressed set of input index vectors for the part (step 902). For this operation, the node removes duplicate input indices from input index vectors in the part to generate the compressed set of input index vectors similar to what is shown in FIG. 5. The node also produces a record of duplicate input indices for the part (step 904). For this operation, the node produces a record that can be used for identifying locations from where indices were removed from input index vectors in the corresponding part when generating the compressed set of input index vectors similar to what is shown in FIG. 5. The node then communicates the record of duplicate input indices to a receiving node (step 906). The receiving node keeps the record of duplicate input indices for use in decompressing compressed lookup data for the part, e.g., as described for FIGS. 7 and 10. The node next (or at substantially the same time as performing step 906) generates compressed lookup data using input index vectors from the compressed set of input index vectors (step 908). For this operation, the node looks up data in the respective embedding table using each index in the compressed set of input index vectors and then writes the lookup data to a corresponding location in the compressed lookup data similar to what is shown in FIG. 6. The node then communicates the compressed lookup data to a receiving node as part of an all-to-all communication (step 910). During this operation, the node communicates the compressed lookup data (i.e., a block of data including at least the compressed lookup data) to the receiving node as one part of an all-to-all communication such as that shown in FIG. 2 as described for FIG. 6.

### Process for Decompressing Compressed Lookup Data

In the described embodiments, nodes perform operations for decompressing compressed lookup data received from other nodes. Generally, for this operation, when processing instances of input data through a model, each node receives, from each other node, compressed lookup data that was generated using a compressed set of input index vectors. Each node then decompresses the compressed lookup data using a record of duplicate input indices to generate decompressed data that is then used for subsequent operations for processing instances of input data though the model. FIG. 10 presents a flowchart illustrating a process for decompressing compressed lookup data in accordance with some embodiments. FIG. 10 is presented as a general example of operations performed in some embodiments. In other embodiments, however, different operations are performed and/or operations are performed in a different order. Additionally, although certain elements are used in describing the process, in some embodiments, other elements perform the operations.

For the example in FIG. 10, assumptions similar to the assumptions made for the example in FIGS. 3 and 5-9 are made. That is, there are assumed to be four nodes, node0-node3. There are also assumed to be twelve embedding tables in total, i.e., embedding tables 0-12, and each node stores, in that node's local memory, a different subset of three of the twelve embedding tables in that node's local memory (i.e., node0 stores embedding tables 0-2, node1 stores embedding tables 3-5, etc.). Each node is additionally assumed to process five instances of input data through the model, with node0 processing instances of input data 0-4, node1 processing instances of input data 5-9, etc.

For the example in FIG. 10 operations similar to those performed in FIG. 7 are presented in flowchart form—and the operations of FIG. 9 are assumed to have been performed (i.e., so the compressed set of input index vectors exists, etc.). For the operations in FIG. 10, operations are described for decompressing compressed lookup data for only one part of a full set of input index vectors (e.g., part 312, etc.). In some embodiments, each node performs similar operations for decompressing compressed lookup data for corresponding parts of a full set of input index vectors. For example, node0 can perform similar operations for each of parts 500-506 (or at least for parts 502-506, as node0 may not itself compress its own lookup data).

The process shown in FIG. 10 starts when node receives a record of duplicate input indices (step 1000). For this operation, the node receives the record of duplicate input indices communicated by another node (e.g., in step 906) as described for FIG. 7. Recall that the record of duplicate input indices is received before the compressed lookup data so that the node can use size of data information in or associated with the record of duplicate input indices for receiving the compressed lookup data. The node subsequently receives the compressed lookup data (step 1002). For this operation, the node receives compressed lookup data such as compressed lookup data 600 similar to what is described for FIG. 7. The node then decompresses the compressed lookup data using the record of duplicate input indices (step 1004). For this operation, the node uses the record of duplicate input indices to identify lookup data that was not included in the compressed lookup data and generate decompressed lookup data such as described for FIG. 7. The node then uses the decompressed lookup data for processing instances of input data through a model (step 1006).

In some embodiments, at least one electronic device (e.g., electronic device 400, etc.) or some portion thereof uses code and/or data stored on a non-transitory computer-readable storage medium to perform some or all of the operations described herein. More specifically, the at least one electronic device reads code and/or data from the computer-readable storage medium and executes the code and/or uses the data when performing the described operations. A computer-readable storage medium can be any device, medium, or combination thereof that stores code and/or data for use by an electronic device. For example, the computer-readable storage medium can include, but is not limited to, volatile and/or non-volatile memory, including flash memory, random access memory (e.g., DDR5 DRAM, SRAM, eDRAM, etc.), non-volatile RAM (e.g., phase change memory, ferroelectric random access memory, spin-transfer torque random access memory, magnetoresistive random access memory, etc.), read-only memory (ROM), and/or magnetic or optical storage mediums (e.g., disk drives, magnetic tape, CDs, DVDs, etc.).

In some embodiments, one or more hardware modules perform the operations described herein. For example, the hardware modules can include, but are not limited to, one or more central processing units (CPUs)/CPU cores, graphics processing units (GPUs)/GPU cores, application-specific integrated circuit (ASIC) chips, field-programmable gate arrays (FPGAs), compressors or encoders, encryption functional blocks, compute units, embedded processors, accelerated processing units (APUs), controllers, requesters, completers, network communication links, and/or other functional blocks. When circuitry (e.g., integrated circuit elements, discrete circuit elements, etc.) in such hardware modules is activated, the circuitry performs some or all of the operations. In some embodiments, the hardware modules include general purpose circuitry such as execution pipelines, compute or processing units, etc. that, upon executing instructions (e.g., program code, firmware, etc.), performs the operations. In some embodiments, the hardware modules include purpose-specific or dedicated circuitry that performs the operations “in hardware” and without executing instructions.

In some embodiments, a data structure representative of some or all of the functional blocks and circuit elements described herein (e.g., electronic device 400 or some portion thereof) is stored on a non-transitory computer-readable storage medium that includes a database or other data structure which can be read by an electronic device and used, directly or indirectly, to fabricate hardware including the functional blocks and circuit elements. For example, the data structure may be a behavioral-level description or register-transfer level (RTL) description of the hardware functionality in a high-level design language (HDL) such as Verilog or VHDL. The description may be read by a synthesis tool which may synthesize the description to produce a netlist including a list of transistors/circuit elements from a synthesis library that represent the functionality of the hardware including the above-described functional blocks and circuit elements. The netlist may then be placed and routed to produce a data set describing geometric shapes to be applied to masks. The masks may then be used in various semiconductor fabrication steps to produce a semiconductor circuit or circuits (e.g., integrated circuits) corresponding to the above-described functional blocks and circuit elements. Alternatively, the database on the computer accessible storage medium may be the netlist (with or without the synthesis library) or the data set, as desired, or Graphic Data System (GDS) II data.

In this description, variables or unspecified values (i.e., general descriptions of values without particular instances of the values) are represented by letters such as N, T, and X. As used herein, despite possibly using similar letters in different locations in this description, the variables and unspecified values in each case are not necessarily the same, i.e., there may be different variable amounts and values intended for some or all of the general variables and unspecified values. In other words, particular instances of N and any other letters used to represent variables and unspecified values in this description are not necessarily related to one another.

The expression “et cetera” or “etc.” as used herein is intended to present an and/or case, i.e., the equivalent of “at least one of” the elements in a list with which the etc. is associated. For example, in the statement “the electronic device performs a first operation, a second operation, etc.,” the electronic device performs at least one of the first operation, the second operation, and other operations. In addition, the elements in a list associated with an etc. are merely examples from among a set of examples—and at least some of the examples may not appear in some embodiments.

The foregoing descriptions of embodiments have been presented only for purposes of illustration and description. They are not intended to be exhaustive or to limit the embodiments to the forms disclosed. Accordingly, many modifications and variations will be apparent to practitioners skilled in the art. Additionally, the above disclosure is not intended to limit the embodiments. The scope of the embodiments is defined by the appended claims.

What is claimed is:

1. An electronic device, comprising:
a plurality of nodes, each node configured to:
generate compressed lookup data to be used for processing instances of input data through a model using input index vectors from a compressed set of input index vectors for each part among multiple parts of a respective set of input index vectors; and
communicate compressed lookup data for a respective part to each other node.

2. The electronic device of claim 1, wherein each node is further configured to:
generate the compressed set of input index vectors for each part of the respective set of input index vectors by:
identifying duplicate input indices in input index vectors in that part; and
generating the compressed set of input index vectors by removing duplicate input indices from input index vectors in that part.

3. The electronic device of claim 2, wherein each node is further configured to:
produce a record of locations of duplicate input indices for each part of the respective set of input index vectors that identifies:
locations of unique input indices in each input index vector in the compressed set of input index vectors for that part;
locations of removed input indices that are duplicates of the unique input indices in each input index vector for that part; and
a number of input indices in the compressed set of input index vectors for that part; and
communicate, to a respective other node, the record of locations of duplicate input indices for that part.

4. The electronic device of claim 2, wherein, when identifying duplicate input indices in each input index vector, the node is further configured to:
identify unique input indices in that input index vector; and
identify input indices in that input index vector that are duplicates of unique input indices in that input index vector.

5. The electronic device of claim 1, wherein processing the instances of input data through the model occurs during:
training operations for training the model; or
operations for using the model after the model has been trained.

6. The electronic device of claim 1, further comprising:
a communication fabric coupled between the nodes;
wherein communicating the compressed lookup data for the respective part to each other node includes performing an all-to-all communication on the communication fabric.

7. The electronic device of claim 1, wherein, when generating the compressed lookup data, each node:
acquires lookup data from at least one embedding table stored in a local memory for that node using input index vectors from the compressed set of input index vectors for each of the parts of the respective set of input index vectors, the lookup data including data from rows of the at least one embedding table, and each input index vector including indices identifying rows of the embedding table.

8. A method for processing instances of input data through a model in an electronic device that includes a plurality of nodes, the method comprising, by each node:
generating compressed lookup data to be used for processing instances of input data through a model using input index vectors from a compressed set of input index vectors for each part among multiple parts of a respective set of input index vectors; and
communicating compressed lookup data for a respective part to each other node.

9. The method of claim 8, further comprising, by each node:
generating the compressed set of input index vectors for each part of the respective set of input index vectors by:
identifying duplicate input indices in input index vectors in that part; and
generating the compressed set of input index vectors by removing duplicate input indices from input index vectors in that part.

10. The method of claim 9, further comprising, by each node:
producing a record of locations of duplicate input indices for each part of the respective set of input index vectors that identifies:
locations of unique input indices in each input index vector in the compressed set of input index vectors for that part;
locations of removed input indices that are duplicates of the unique input indices in each input index vector for that part; and
a number of input indices in the compressed set of input index vectors for that part; and
communicating, to a respective other node, the record of locations of duplicate input indices for that part.

11. The method of claim 9, wherein identifying duplicate input indices in each input index vector includes:
identifying unique input indices in that input index vector; and
identifying input indices in that input index vector that are duplicates of unique input indices in that input index vector.

12. The method of claim 8, wherein generating the compressed lookup data includes, by each node:
acquiring lookup data from at least one embedding table stored in a local memory for that node using input index vectors from the compressed set of input index vectors for each of the parts of the respective set of input index vectors, the lookup data including data from rows of the at least one embedding table, and each input index vector including indices identifying rows of the embedding table.

13. The method of claim 8, wherein processing the instances of input data through the model occurs during:
training operations for training the model; or
operations for using the model after the model has been trained.

14. The method of claim 8, wherein communicating the compressed lookup data for the respective part to each other node includes:
performing an all-to-all communication on a communication fabric coupled between the nodes.

15. An electronic device, comprising:
a plurality of nodes, each node configured to:
receive, from each other node, compressed lookup data; and
decompress the compressed lookup data received from each other node to generate decompressed lookup data to be used for processing instances of input data through a model, the decompressing including:
receiving a record of locations of duplicate input indices in a part of a respective set of input index vectors from that other node;
identifying locations of missing duplicate lookup data in the compressed lookup data from that other node using the record of locations of duplicate input indices; and
copying missing duplicate lookup data from given locations in the compressed lookup data from that other node to the locations.

16. The electronic device of claim 15, wherein:
the model is a recommendation model; and
using the decompressed lookup data for processing instances of input data through the model includes using the decompressed lookup data as an input within the recommendation model.

17. The electronic device of claim 15, wherein using the decompressed lookup data for processing instances of input data through the model includes:
performing an accumulation operation on the decompressed lookup data, the accumulation operation including combining selected lookup data in the decompressed lookup data to form combined lookup data.

18. A method for processing instances of input data through a model in an electronic device that includes a plurality of nodes, the method comprising, by each node:
receiving, from each other node of the plurality of nodes, compressed lookup data; and
decompressing the compressed lookup data received from each other node to generate decompressed lookup data to be used for processing instances of input data through a model, the decompressing including:
receiving a record of locations of duplicate input indices in a part of a respective set of input index vectors from that other node;
identifying locations of missing duplicate lookup data in the compressed lookup data from that other node using the record of locations of duplicate input indices; and
copying missing duplicate lookup data from given locations in the compressed lookup data from that other node to the locations.

19. The method of claim 18, wherein:
the model is a recommendation model; and
using the decompressed lookup data for processing instances of input data through the model includes using the decompressed lookup data as an input within the recommendation model.

20. The method of claim 18, wherein using the decompressed lookup data for processing instances of input data through the model includes:
performing an accumulation operation on the decompressed lookup data, the accumulation operation including combining selected lookup data in the decompressed lookup data to form combined lookup data.
